(19) United States
(12) Patent Application Publication
(10) Pub. No.: US 2023/0114933 A1
(43) Pub. Date: Apr. 13, 2023

(54) GRAPHENE INTERCONNECT STRUCTURE, ELECTRONIC DEVICE INCLUDING GRAPHENE INTERCONNECT STRUCTURE, AND METHOD OF PREPARING GRAPHENE INTERCONNECT STRUCTURE

(71) Applicant: Samsung Electronics Co., Ltd., Suwon-si (KR)

(72) Inventors: Changhyun KIM, Suwon-si (KR); Kyung-Eun BYUN, Suwon-si (KR); Keunwook SHIN, Suwon-si (KR); Changseok LEE, Gwacheon-si (KR); Baekwon PARK, Suwon-si (KR)

(73) Assignee: Samsung Electronics Co., Ltd., Suwon-si (KR)

(21) Appl. No.: 17/958,653

(22) Filed: Oct. 3, 2022

(30) Foreign Application Priority Data
Oct. 7, 2021 (KR) 10-2021-0133454
Sep. 28, 2022 (KR) 10-2022-0123480

(51) Int. Cl. H01L 21/02; H01L 23/532; C23C 16/40; C23C 16/455; H01L 21/768

(52) U.S. Cl. CPC H01L 21/0228; H01L 21/02274; H01L 23/53276; C23C 16/402; C23C 16/45553; H01L 21/02164; H01L 21/76843

(57) ABSTRACT

Provided are a graphene interconnect structure, an electronic device including the graphene interconnect structure, and a method of manufacturing the graphene interconnect structure. The graphene interconnect structure may include: a first oxide dielectric material layer; a second oxide dielectric material layer on a surface of the first oxide dielectric material layer and having a dielectric constant greater than that of the first oxide dielectric material layer; and a graphene layer on a surface of the second oxide dielectric material layer opposite to the surface on which the first oxide dielectric material layer is located.

### CROSS-REFERENCE TO RELATED APPLICATIONS

This application is based on and claims priority under 35 U.S.C. § 119 to Korean Patent Application Nos. 10-2021-0133454, filed on Oct. 7, 2021, and 10-2022-0123480, filed on Sep. 28, 2022, in the Korean Intellectual Property Office, the disclosure of each of which is incorporated by reference herein in its entirety.

### BACKGROUND

### 1. Field

The present disclosure relates to a graphene interconnect structure, an electronic device including the graphene interconnect structure, and a method of manufacturing the graphene interconnect structure.

### 2. Description of the Related Art

In recent years, the size of semiconductor devices has been gradually reduced to achieve high integration of semiconductor devices. To this end, it is necessary to reduce a line width of the conductive wiring consisting of metal or metal alloy in the interconnect structure. When the line width of the conductive wiring is reduced, current density in the conductive wiring is increased, and as a result, the resistance of the conductive wiring is increased. The increase in resistance of the conductive wiring may cause electromigration of metal or metal alloy atoms constituting the conductive wiring, thereby causing defects in the conductive wiring. To overcome such defects, there is a demand for a graphene interconnect structure having two-dimensional low resistance as a novel material replacing metal or metal alloy, an electronic device including the same, and a method of manufacturing the graphene interconnect structure.

### SUMMARY

Provided are graphene interconnect structures having a low resistance.

Provided are electronic devices including the graphene interconnect structure.

Provided are methods of manufacturing the graphene interconnect structure.

Additional aspects will be set forth in part in the description which follows and, in part, will be apparent from the description, or may be learned by practice of the presented embodiments of the disclosure.

According to an embodiment, a graphene interconnect structure may include: a first oxide dielectric material layer; a second oxide dielectric material layer on a surface of the first oxide dielectric material layer and having a dielectric constant greater than a dielectric constant of the first oxide dielectric material layer; and a graphene layer on a first surface of the second oxide dielectric material layer opposite to a second surface of the second oxide dielectric material layer. The second surface of the second oxide dielectric material layer may be on the first oxide dielectric material layer.

In some embodiments, an areal oxygen density of the first oxide dielectric material layer may be different from an areal oxygen density of the second oxide dielectric material layer.

In some embodiments, a work function of the graphene layer may vary due to a dipole moment generated at an interface between the first oxide dielectric material layer and the second oxide dielectric material layer.

In some embodiments, a specific resistance may be reduced by about 1.1 times to about 10 times according to a change in the work function of the graphene layer in the graphene interconnect structure.

In some embodiments, the first oxide dielectric material layer may include an SiCOH material.

In some embodiments, the first oxide dielectric material layer may include one of tetramethylcyclotetrasiloxane (TOMCATS), octamethylcyclotetrasiloxane (OMCATS), cyclic siloxane 1,1,3,3-tetrahydrido-1,3-disilacyclobutane, 1,1,3,3-tetramethoxy(ethoxy)-1,3 disilacyclobutane, 1,3-dimethyl-1,3-dimethoxy-1,3-disilacyclobutane, 1,3-disilacyclobutane, 1,3-dimethyl-1,3-dihydrido-1,3-disilylcyclobutane, 1,1,3,3-tetramethyl-1,3-disilacyclobutane, 1,1,3,3,5,5-hexamethoxy-1,3,5-trisilane, 1,1,3,3,5,5-hexahydrido-1,3,5-trisilane, 1,1,3,3,5,5-hexamethyl-1,3,5-trisilane, 1,1,1,3,3,3-hexamethoxy(ethoxy)-1,3-disilapropane, 1,1,3,3-tetramethoxy-1-methyl-1,3-disilabutane, 1,1,3,3-tetramethoxy-1,3-disilapropane, 1,1,1,3,3,3-hexahydrido-1,3-disilapropane, 3-(1,1-dimethoxy silaethyl)-1,4,4-trimethoxy-1-methyl-1,4-disilpentane, methoxymethane 2-(dimethoxysilamethyl)-1,1,4-trimethoxy-1,4-disilabutane, methoxymethane 1,1,4-trimethoxy-1,4-disila-2-(trimethoxysilylmethyl) butane, dimethoxymethane, methoxymethane, 1,1,1,5.5.5-hexamethoxy-1,5-disilapentane, 1,1,5,5-tetramethoxy-1,5-disilahexane, 1,1,1,1,4,4,4-hexamethoxy (ethoxy)-1,4-disilylbutane, 1,1,1,4,4,4-hexahydrido-1,4-disilabutane, 1,1,4,4-tetramethoxy(ethoxy)-1,4-dimethyl-1,4-disilabutane, 1,4-bis-trimethoxy(ethoxy)silyl benzene, 1,4-bis-dimethoxymethylsilyl benzene, 1,4-bis-trihydrosilyl benzene, 1,1,1,4,4,4-hexamethoxy (ethoxy)-1,4-disilabut-2-ene, 1,1,1,4,4,4-hexamethoxy(ethoxy)-1,4-disilabut-2-yne, 1,1,3,3-tetramethoxy(ethoxy)-1,3-disilolane, 1,1,3,3-tetramethyl 1,3-disilolane, 1,1,3,3-tetramethoxy(ethoxy)-1,3-disilane, 1,3-dimethoxy(ethoxy)-1,3-dimethyl-1,3-disilane, 1,3-disilane, 1,3-dimethoxy-1,3-disilane, 1,1-dimethoxy (ethoxy)-3.3-dimethyl-1-propyl-3-silabutane, 2-silapropane, or a combination thereof.

In some embodiments, the first oxide dielectric material layer may further include porous SiO₂, SiO₂ doped with fluorine, or amorphous boron nitride.

In some embodiments, the second oxide dielectric material layer may include a compound represented by Formula 1:

AₓO_{y} Formula 1

wherein, in Formula 1, A may be at least one selected from Al, Ti, Zr, Hf, Mg, Si, Ge, Y, Lu, La, and Sr, and 0<x≥2, and 0<y≥3.

In some embodiments, the second oxide dielectric material layer may include at least one of Al₂O₃, TiO₂, ZrO₂, HfO₂, MgO, SiO₂, GeO₂, Y₂O₃, Lu₂O₃, La₂O₃, and SrO.

In some embodiments, a thickness of the second oxide dielectric material layer may be in a range of about 0.3 nm to about 5 nm.

In some embodiments, the graphene layer may be directly grown on the surface of the second oxide dielectric material layer opposite to the surface on which the first oxide dielectric material layer is located.

In some embodiments, a grain size of the graphene layer may be in a range of about 10 nm to about 1 μm.

In some embodiments, the graphene layer may include 1 to 7 layers.

According to an embodiment, an electronic device may include: a substrate; and the graphene interconnect structure.

According to an embodiment, a method of manufacturing a graphene interconnect structure may include: preparing a first oxide dielectric material layer; forming a second oxide dielectric material layer by atomic layer deposition (ALD) on a surface of the first oxide dielectric material layer; and directly growing a graphene layer by chemical vapor deposition (CVD) on a surface of the second oxide dielectric material layer. A dielectric constant of the second oxide dielectric material layer may be greater than a dielectric constant of the first oxide dielectric material layer. The second oxide dielectric material layer may include a compound represented by Formula 1:

AₓO_{y} Formula 1

wherein, in Formula 1, A may be at least one selected from Al, Ti, Zr, Hf, Mg, Si, Ge, Y, Lu, La, and Sr, and 0<x≥2, and 0<y≥3.

In some embodiments, the first oxide dielectric material layer may include at least one of SiCOH material, porous SiO₂, SiO₂ doped with fluorine, and amorphous boron nitride.

In some embodiments, the forming the second oxide dielectric material layer by ALD may use a precursor and the precursor may include at least one of (CH₃)₃Al, TiCl₄, trimethoxy(pentamethylcyclopentadienyl)titanium ((CpMe₅)Ti(OMe)₃), tetrakis(dimethylamino)titanium, Zr[N(CH₃)₂]₄, (dimethylamino)cyclopentadientyl zirconium, ZrCl₄, Hf[N(CH₃)₂]₄, Hf(BH₄)₄, HfCl₄, bis(cyclopentadienyl)magnesium (Mg(Cp)₂), bis(ethylcyclopentadienyl)magnesium (Mg(CpEt)₂), tris(dimethylamino)silane, bis(ethyl-methyl-amino)silane, 1,2-bis(diisopropylamino)disilane, Ge(N, N′—R,R-en)[N(CH₃₎₂]₂ (wherein R is isopropyl or t-butyl), tris(N,N′-diisopropyl-formamidinato)yttrium, {Lu[Cp(Si(CH₃))₂Cl]₂ dimer, tris(isopropyl-cyclopentadienyl)lanthanum (La(iPrCp)₃), strontium bis(isopropylcyclopentadienyl) (Sr(iPrCp)₂), strontium bis(1,2,4-triisopropylcyclopentadienyl) (Sr(1,2,4-iPr₃Cp)₂), strontium bis(tri(isopropyl)cyclopentadienyl (Sr(C₅iPr₃H₂)₂), strontium bis(pentamethylcyclopentadienyl) (Sr(1,2,4-C₅Me₅)₂), strontium bis(n-propyltetramethylcyclopentadienyl) (Sr(nPrMe₄Cp)₂), and strontium bis(tri-tert-butylcyclopentadienyl) (Sr(tBu₃Cp)₂).

In some embodiments, in the directly growing of the graphene layer, the CVD may be performed at a temperature in a range of about 250° C. to about 700° C.

According to an embodiment, a graphene interconnect structure may include: a first oxide dielectric material layer; a graphene layer on the first oxide dielectric material layer; and a second oxide dielectric material layer between the first oxide dielectric material layer and the graphene layer. The first oxide dielectric material layer and the second oxide dielectric material layer may contact each other at an interface and may have a structural imbalance at the interface.

In some embodiments, the first oxide dielectric material layer may include a SiCOH material, and the second oxide dielectric material layer may include at least one of Al₂O₃, TiO₂, ZrO₂, HfO₂, MgO, SiO₂, GeO₂, Y₂O₃, Lu₂O₃, La₂O₃, and SrO.

In some embodiments, the first oxide dielectric material layer may further include porous SiO₂, SiO₂ doped with fluorine, or amorphous boron nitride.

In some embodiments, a thickness of the second oxide dielectric material layer may be in a range of about 0.3 nm to about 5 nm.

In some embodiments, the graphene layer may be directly on a surface of the second oxide dielectric material layer, and the graphene layer may include 1 to 7 layers.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an interconnect structure according to an embodiment;

FIG. 2 is a schematic view illustrating a change in Fermi energy level (EF) of a graphene layer due to a dipole generated at an interface between a first oxide dielectric material layer and a second oxide dielectric material layer in an interconnect structure according to an embodiment;

FIG. 3 is a schematic view illustrating a change in Fermi energy level (EF) of a graphene layer due to a dipole generated at an interface between a first oxide dielectric material layer and a second oxide dielectric material layer in an interconnect structure according to another embodiment;

FIG. 4 is a schematic cross-sectional view of a graphene interconnect structure according to another embodiment;

FIG. 5 is a schematic cross-sectional view of a graphene interconnect structure according to still another embodiment; and

FIGS. 6A to 6C and 7A to 7B are cross-sectional views of electronic devices according to some example embodiments.

### DETAILED DESCRIPTION

Reference will now be made in detail to embodiments, examples of which are illustrated in the accompanying drawings, wherein like reference numerals refer to like elements throughout. In this regard, the presented embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, with reference to attached drawings, a graphene interconnect structure and a method of manufacturing the same according to an embodiment will be described in detail. However, these are for illustrative purposes only and are not intended to limit the scope of inventive concepts. The scope of inventive concepts is indicated by the claims rather than by the detailed description.

Like reference numerals in the drawings denotes like components, and sizes of components in the drawings may be exaggerated for clarity and convenience of explanation. In the present specification, the expression “at least one type”, “at least one”, “one type or more”, or “one or more” before the components may supplement the list of all components, and the expression may not mean that the individual components of the description may be supplemented. In the present specification, the term “combination” includes mixtures, alloys, reaction products, or complex forms of one component and another component, unless otherwise stated. It will be further understood that the terms “comprises” and/or “comprising” used herein specify the presence of stated features or components, and they do not preclude the presence of one or more other features or components but add the presence thereof. Unless otherwise stated or otherwise clearly contradicted by context herein, it should be construed to include both the singular and the plural. The term “or” means “and/or” unless otherwise stated.

In the present specification, “one embodiment”, “embodiment”, or the like means that a specific element described in relation to Examples is included in at least one of the Examples described herein, and the specific element may or may not exist in another Example. Also, it should be understood that the described elements may be combined in any suitable manner in various Examples.

Throughout the specification, it will be understood that when a component is referred to as being “on top of” or “on” another component, the component may be directly on the other component or indirectly thereon, while other elements intervening therebetween. Also, it should be understood that the described elements may be combined in any suitable manner in various Examples. Unless otherwise stated, all terms including technical and scientific terms used herein have the same meaning as the terms commonly understood by one of ordinary skill in the art to which the present disclosure pertains.

All patents, patent applications and other references cited are incorporated herein by reference in their entirety. However, to the extent a term herein contradicts or conflicts with a term in the incorporated reference, the term in this specification takes precedence over the conflicting term in the incorporated reference. Although specific embodiments have been described, alternatives, modifications, variations, improvements, and substantial equivalents that are not currently anticipated may occur to the applicant or one of ordinary skill in the art. Accordingly, the appended claims, which may be filed and amended, are intended to cover all such alternatives, modifications, variations, improvements, and substantial equivalents.

When an electric field is applied to a dielectric substance, a dielectric material, a dielectric polarization may occur in which polarized molecules are aligned. A degree of polarization may be proportional to the electric field. A degree to which the degree of dielectric polarization is proportional to the applied electric field may be expressed as a permittivity. A permittivity (c) of a dielectric substance or a dielectric material may be referred to as a dielectric constant. Since the term “dielectric constant” as used herein may not be an absolute numerical value, and thus, the expressions may be used interchangeably.

In the present specification, the term “graphene” refers to a polycyclic aromatic molecule in which a plurality of carbon atoms are connected to each other by a covalent bond and arranged in one plane. A plurality of carbon atoms connected by the covalent bond may form a 6-membered ring as a basic repeating unit, but the basic repeating unit may also further include a 5-membered ring and/or a 7-membered ring. The polycyclic aromatic molecules may form a single atom layer in a sheet structure or a network structure arranged in a plane in which a plurality of interconnected plates in the form of small film pieces, or a combination thereof. The polycyclic aromatic molecules may consist of a single layer or a plurality of layers stacked on each other, each having a sheet structure and/or a network structure.

In the present specification, the term “graphene interconnect structure” refers to an interconnect structure including a graphene layer, which itself is used as an interconnect. The graphene layer of the interconnect structure may be distinct from a graphene layer used for a capping layer and/or barrier layer.

As an interconnect structure, metal, for example, copper, has been widely used. When such a metal interconnect structure is fabricated on a nano-scale, a specific resistance of the metal interconnect structure is rapidly increased. This is because, since the metal is a conductor, and electrons are all filled up to a Fermi energy level, a change in specific resistance may not occur.

The present inventors propose a graphene interconnect structure of a novel structure instead of a metal interconnect structure by considering such a point.

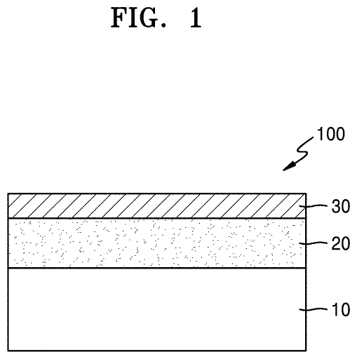

FIG. 1 is a schematic cross-sectional view of a graphene interconnect structure 100 according to an embodiment.

As shown in FIG. 1, the graphene interconnect structure 100 may include: a first oxide dielectric material layer 10; a second oxide dielectric material layer 20 disposed on a surface of the first oxide dielectric material layer 10 and having a dielectric constant greater than that of the first oxide dielectric material layer 10; and a graphene layer 30 on a surface of the second oxide dielectric material layer 20 opposite to the surface on which the first oxide dielectric material layer 10 is located.

An areal oxygen density of the first oxide dielectric material layer 10 may be different from an areal oxygen density of the second oxide dielectric material layer 20. An areal oxygen density refers to the number of oxygen atoms present in a unit area. Such a difference in areal oxygen density is due to a structural imbalance between the first oxide dielectric material layer and the second oxide dielectric material layer. Such a structural imbalance may be resolved by migration of oxygen atoms. That is, oxygen atoms may migrate from the first oxide dielectric material layer 10 or the second oxide dielectric material layer 20 having a high areal oxygen density to the second oxide dielectric material layer 20 or the first oxide dielectric material layer 10 having a low areal oxygen density. The migrating oxygen atoms may be in O²⁻ anion form. Migration of oxygen atoms may create oxygen vacancy in the first oxide dielectric material layer 10 or the second oxide dielectric material layer 20 having a high areal oxygen density and excess oxygen in the second oxide dielectric material layer 20 or the first oxide dielectric material layer 10 having a low areal oxygen density. Thus, the second oxide dielectric material layer 20 or the first oxide dielectric material layer 10 having a low areal oxygen density may have a negative charge, and the first oxide dielectric material layer 10 or the second oxide dielectric material layer 20 having a high areal oxygen density may have a positive change. Accordingly, a dipole from a positive charge to a negative change may be generated at an interface between the first oxide dielectric material layer 10 and the second oxide dielectric material layer 20. Such a dipole may raise or lower a Fermi energy level (EF) of the second oxide dielectric material layer 20 at an interface between the first oxide dielectric material layer 10 and the second oxide dielectric material layer 20. A work function of the graphene layer 30 on the second oxide dielectric material layer 20 may change.

That is, a work function of the graphene layer 30 may vary due to a dipole moment generated at an interface between the first oxide dielectric material layer 10 and the second oxide dielectric material layer 20. The change in work function of the graphene layer 30 may influence to a specific resistance of the graphene interconnect structure 100. A specific resistance of the graphene interconnect structure 100 may be reduced by about 1.1 times to about 10 times according to a change in the work function of the graphene layer 30 in the graphene interconnect structure 100.

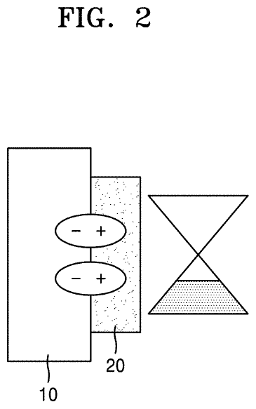

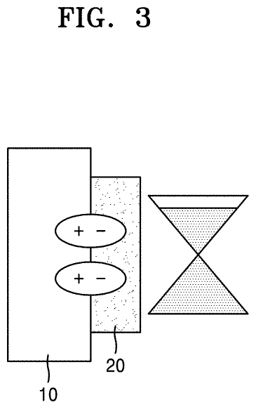

FIG. 2 is a schematic view illustrating a change in Fermi energy level (EF) of a graphene layer due to a dipole generated at an interface between a first oxide dielectric material layer and a second oxide dielectric material layer in an interconnect structure according to an embodiment. FIG. 3 is a schematic view illustrating a change in Fermi energy level (EF) of a graphene layer due to a dipole generated at an interface between a first oxide dielectric material layer and a second oxide dielectric material layer in an interconnect structure according to another embodiment;

As shown in FIG. 2, as the areal oxygen density of the second oxide dielectric material layer 20 is greater than that of the first oxide dielectric material layer 10, O²⁻ anion oxygen atoms may migrate from the second oxide dielectric material layer 20 to the first oxide dielectric material layer 10, and thus, the second oxide dielectric material layer 20 may have a positive charge, and the first oxide dielectric material layer 10 may have a negative charge. A dipole from a positive charge to a negative change may be generated at an interface between the first oxide dielectric material layer 10 and the second oxide dielectric material layer 20. As a result, the Fermi energy level of the second oxide dielectric material layer 20 may be lowered.

As shown in FIG. 3, in contrast with FIG. 2, as the areal oxygen density of the first oxide dielectric material layer 10 is greater than that of the second oxide dielectric material layer 20, O²⁻ anion oxygen atoms may migrate from the first oxide dielectric material layer 10 to the second oxide dielectric material layer 20, and thus, the first oxide dielectric material layer 10 may have a positive charge, and the second oxide dielectric material layer 20 may have a negative charge. A dipole from a positive charge to a negative change may be generated at an interface between the first oxide dielectric material layer 10 and the second oxide dielectric material layer 20. As a result, the Fermi energy level of the second oxide dielectric material layer 20 may be raised. As shown in FIGS. 2 and 3, a work function of the graphene layer 30 on the second oxide dielectric material layer 20 may change.

The first oxide dielectric material layer 10 may include an SiCOH material. The SiCOH material may include Si, C, O, or H atoms, and these atoms in the dielectric material may be bound via a covalent bond to form Si—O, Si—C, Si—H, C—H, or C—C. The SiCOH material may be a dielectric material having a low dielectric constant of about 2.8 or less. The SiCOH material may be porous or non-porous. The SiCOH material may form a two-dimensional network of covalent bonds. For example, the SiCOH material may have about 5 atom % to about 40 atom % of Si; about 5 atom % to about 45 atom % of C; about 0 atom % to about 50 atom % of O; and about 5 atom % to about 55 atom % of H.

The first oxide dielectric material layer 10 may include tetramethylcyclotetrasiloxane (TOMCATS), octamethylcyclotetrasiloxane (OMCATS), cyclic siloxane 1,1,3,3-tetrahydrido-1,3-disilacyclobutane, 1,1,3,3-tetramethoxy(ethoxy)-1,3 disilacyclobutane, 1,3-dimethyl-1,3-dimethoxy-1,3-disilacyclobutane, 1,3-disilacyclobutane, 1,3-dimethyl-1,3-dihydrido-1,3-disilylcyclobutane, 1,1,3,3-tetramethyl-1,3-disilacyclobutane, 1,1,3,3,5,5-hexamethoxy-1,3,5-trisilane, 1,1,3,3,5,5-hexahydrido-1,3,5-trisilane, 1,1,3,3,5,5-hexamethyl-1,3,5-trisilane, 1,1,1,3,3,3-hexamethoxy(ethoxy)-1,3-disilapropane, 1,1,3,3-tetramethoxy-1-methyl-1,3-disilabutane, 1,1,3,3-tetramethoxy-1,3-disilapropane, 1,1,1,3,3,3-hexahydrido-1,3-disilapropane, 3-(1,1-dimethoxy-1-silaethyl)-1,4,4-trimethoxy-1-methyl-1,4-disilpentane, methoxymethane 2-(dimethoxysilamethyl)-1,1,4-trimethoxy-1,4-disilabutane, methoxymethane 1,1,4-trimethoxy-1,4-disila-2-(trimethoxysilylmethyl) butane, dimethoxymethane, methoxymethane, 1,1,1,5.5.5-hexamethoxy-1,5-disilapentane, 1,1,5,5-tetramethoxy-1,5-disilahexane, 1,1,1,1,4,4,4-hexamethoxy (ethoxy)-1,4-disilylbutane, 1,1,1,4,4,4-hexahydrido-1,4-disilabutane, 1,1,4,4-tetramethoxy(ethoxy)-1,4-dimethyl-1,4-disilabutane, 1,4-bis-trimethoxy(ethoxy)silyl benzene, 1,4-bis-dimethoxymethylsilyl benzene, 1,4-bis-trihydrosilyl benzene, 1,1,1,4,4,4-hexamethoxy (ethoxy)-1,4-disilabut-2-ene, 1,1,1,4,4,4-hexamethoxy(ethoxy)-1,4-disilabut-2-yne, 1,1,3,3-tetramethoxy(ethoxy)-1,3-disilolane, 1,1,3,3-tetramethyl 1,3-disilolane, 1,1,3,3-tetramethoxy(ethoxy)-1,3-disilane, 1,3-dimethoxy(ethoxy)-1,3-dimethyl-1,3-disilane, 1,3-disilane, 1,3-dimethoxy-1,3-disilane, 1,1-dimethoxy (ethoxy)-3.3-dimethyl propyl-3-silabutane, 2-silapropane, or a combination thereof.

The first oxide dielectric material layer 10 may further include porous SiO₂, SiO₂ doped with fluorine, or amorphous boron nitride. For example, the first oxide dielectric material layer 10 may be the porous SiO₂. The porous SiO₂ may have nanopores. A diameter of the nanopores may be in a range of about 0.1 nm to about 50 nm. A porosity of the porous SiO₂ may be in a range of about 0.5% to about 50%, based on the total volume.

The second oxide dielectric material layer 20 may include a compound represented by Formula 1:

AₓO_{y} Formula 1

wherein, in Formula 1, A may be at least one selected from Al, Ti, Zr, Hf, Mg, Si, Ge, Y, Lu, La, and Sr, and 0<x≥2, and 0<y≥3.

The second oxide dielectric material layer 20 may include at least one oxide selected from Al₂O₃, TiO₂, ZrO₂, HfO₂, MgO, SiO₂, GeO₂, Y₂O₃, Lu₂O₃, La₂O₃, and SrO. The second oxide dielectric material layer 20 may further include a dopant, according to a need. Examples of the dopant may include at least one of Si, Al, Zr, Y, La, Gd, Sr, and Hf, but embodiments are not limited thereto.

A thickness of the second oxide dielectric material layer 20 may be in a range of about 0.3 nm to about 5 nm. When a thickness of the second oxide dielectric material layer 20 is within this range, a dipole generated at an interface between the first oxide dielectric material layer 10 and the second oxide dielectric material layer 20 may be effectively transferred to the graphene layer 30 to thereby reduce the specific resistance. Accordingly, RC delay may be limited and/or prevented, and reliability may be secured.

The graphene layer 30 may be directly grown on the surface of the second oxide dielectric material layer 20 opposite to the surface on which the first oxide dielectric material layer 10 is located.

A grain size of the graphene layer 30 may be in a range of about 10 nm to about 1 μm.

The graphene layer 30 may be directly grown on the opposite surface of the second oxide dielectric material layer 20 by chemical vapor deposition (CVD). The graphene layer 30 may have a sufficiently low specific resistance to be used as an interconnect structure. In addition, the graphene layer 30 may have excellent processability, as compared with the graphene layer transferred after growth using a catalyst on a separate substrate, and a graphene layer may be effectively realized even in a structure with a narrow line width.

The graphene layer 30 may include 1 to 7 layers.

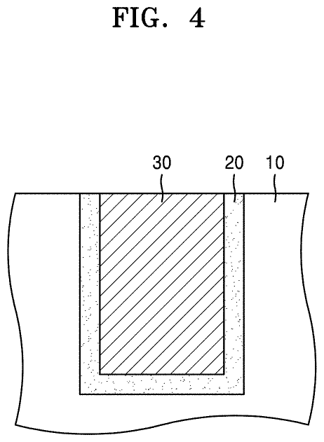

FIG. 4 is a schematic cross-sectional view of a graphene interconnect structure according to another embodiment. As shown in FIG. 4, a trench may be formed in the first oxide dielectric material layer 10, the second oxide dielectric material layer 20 may be arranged to surround an internal wall surface and an undersurface of the trench, and the graphene layer 30 may be arranged to fill the trench in which the second oxide dielectric material layer 20 may be located. Examples of the method of forming the first oxide dielectric material layer 10 may include a photolithography process and an etching process such as reactive ion etching (RIE). As shown in FIG. 4, one trench may be formed in the first oxide dielectric material layer 10, and the trench may not be in contact with the first oxide dielectric material layer 10. However, at least one trench may be formed, and the at least one trench may be formed to be in contact with the first oxide dielectric material layer 10. In some embodiments, at least one cylinder may be formed in the first oxide dielectric material layer 10, the second oxide dielectric material layer 20 may be located to surround an internal wall surface and an undersurface of the at least one cylinder, and the graphene layer 30 may be located to fill in the at least one cylinder in which the second oxide dielectric material layer 20 may be located.

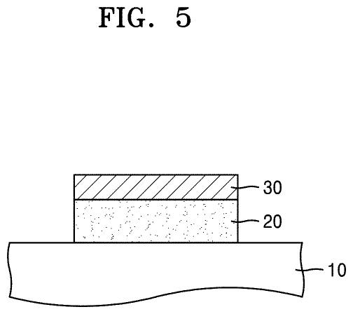

FIG. 5 is a schematic cross-sectional view of a graphene interconnect structure according to still another embodiment. As shown in FIG. 5, the second oxide dielectric material layer 20 and the graphene layer 30 may be sequentially stacked on a surface of the first oxide dielectric material layer 10, the second oxide dielectric material layer 20 and the graphene layer 30 each having an area different from that of the first oxide dielectric material layer 10.

An electronic device according to one or more embodiments may include: a substrate; and the graphene interconnect structure.

The substrate may include at least one of a Group IV semiconductor material, a semiconductor compound, an insulating material, and a metal. For example, the substrate may include a Group IV semiconductor material, such as Si, Ge, or Sn. In some embodiments, for example, a substrate may include at least one of Si, Ge, C, Zn, Cd, Al, Ga, In, B, C, N, P, S, Se, As, Sb, Te Ta, Ru, Rh, Ir, Co, Ta, Ti, W, Pt, Au, Ni, and Fe. For example, the substrate may include Si, Ge, SiC, SiGe, SiGeC, Ge alloy, GaAs, InAs, or InP. The substrate may include a single layer or a plurality of layers in which different materials are stacked.

For example, the substrate may include a silicon-on-insulator (SOI) substrate or a silicon germanium-on-insulator (SGOI) substrate. For example, the substrate may further include N or F as a SiCOH-based composition and may include pores for reducing a permittivity. The substrate may further include a dopant.

The substrate may include at least one semiconductor device. For example, semiconductor device may include at least one of a transistor, a capacitor, a diode, and a resistor. For example, the semiconductor device may be a transistor. However, the semiconductor device is not particularly limited thereto, and any suitable semiconductor device available in the art may be used.

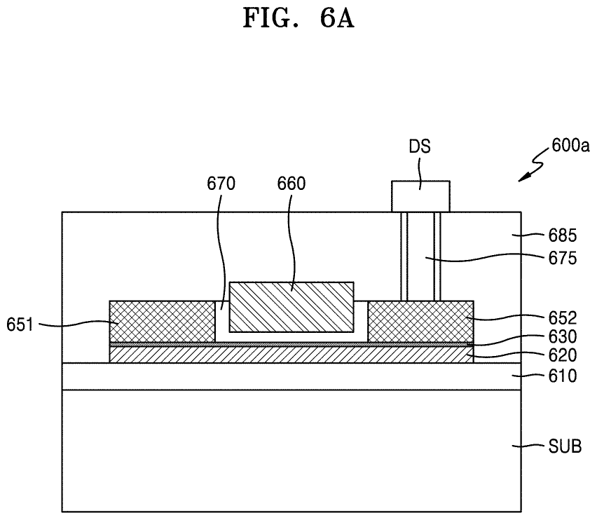

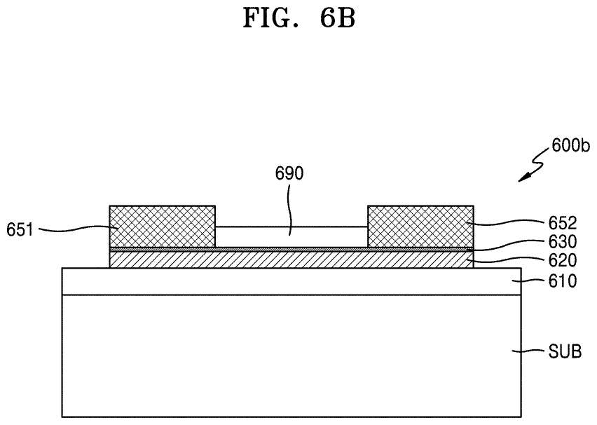

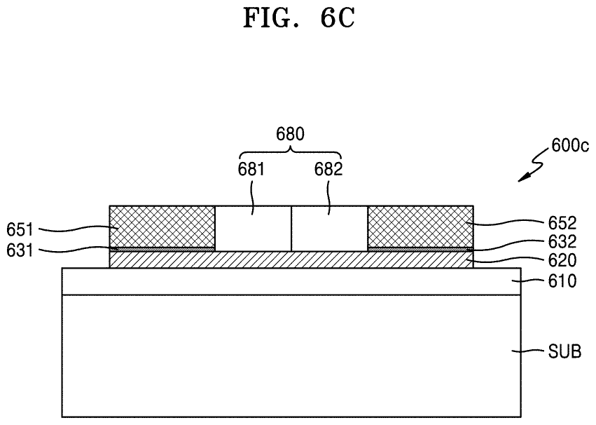

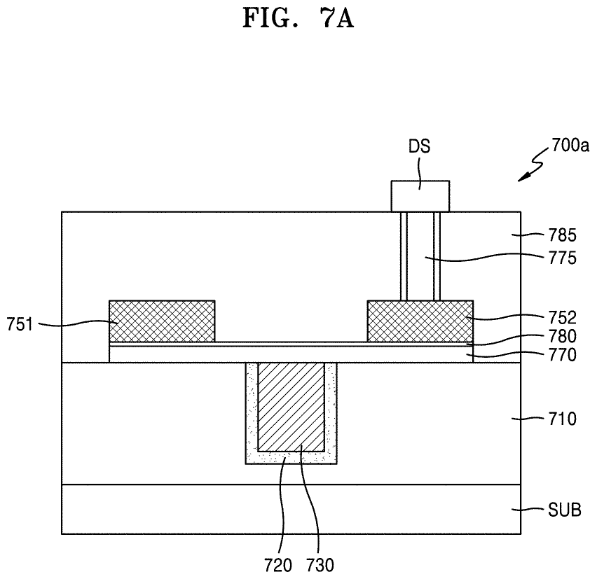

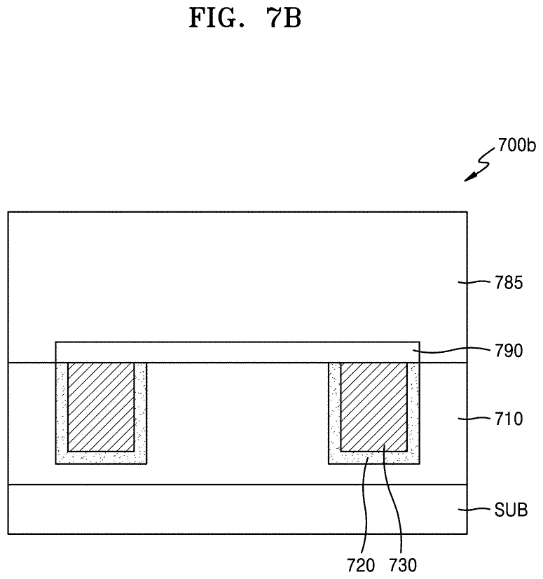

FIGS. 6A to 6C and 7A to 7B are cross-sectional views of electronic devices according to some example embodiments.

Referring to FIG. 6A, in an embodiment, an electronic device 600a may be formed as a transistor connected to a data storage DS. The electronic device 600a may include a substrate SUB, a first oxide dielectric material layer 610 on the substrate, a second oxide dielectric material layer 620 on the first oxide dielectric material layer 610, and a graphene layer 630 on the second oxide dielectric material layer 620. The first and second oxide dielectric material layers 610 and 620 respectively may be formed of the same materials as the first and second oxide dielectric material layers 10 and 20 described above with reference to FIGS. 1, 4, and 5. A work function of the graphene layer 630 may vary due to a dipole moment at an interface between the first and second oxide dielectric material layers 610 and 620.

A source electrode 651 and a drain electrode 652 are provided on the upper surface of the graphene layer 630 and spaced apart from each other. A gate insulating layer 670 may be provided on the graphene layer 630 between the source electrode 651 and the drain electrode 652, and a gate electrode 660 may be provided on the gate insulating layer 670. The gate electrode 660 may be spaced apart from the source electrode 651, drain electrode 652, and graphene layer 630 with the gate insulating layer 670 therebetween.

The electronic device 600a may further include an insulating layer 685, such as silicon oxide, covering the source electrode 651, gate insulating layer 670, gate electrode 660, and drain electrode 652. The data storage DS (e.g., capacitor) may be on the insulating layer 685. A contact 675 including an electrically conductive material, such as a metal or metal alloy, may connect the data storage DS to the drain electrode 652.

Referring to FIG. 6B, in an embodiment, an electronic device 600b may differ from the electronic device 600a in FIG. 6A because the gate insulating layer 670, gate electrode 660, insulating layer 685, contact 675, and data storage DS may be omitted. The electronic device 600b may provide a resistor. Optionally, a conductive layer 690 may be formed between the electrodes 651 and 652. The conductive layer 690 may include a conductive material, such as a metal or metal alloy. Optionally, a portion of the graphene layer 630 below the conductive layer 690 may be removed, in which case the graphene layer 630 has separate graphene layers like the graphene layers 631 and 632 in FIG. 6C.

Referring to FIG. 6C, in an embodiment, an electronic device 600c may differ from the electronic device 600b because a diode structure 680 be provided on the second oxide dielectric material layer 620 between the electrodes 651 and 652. The diode structure 680 may include a first portion 681 contacting the electrode 651 and a second portion 682 contacting the electrode 652. The diode structure 680 may be formed of a semiconductor material, such as polysilicon, and the first and second portions 681 and 682 may be doped with impurities of different conductivity types. Instead of the graphene layer 630 shown in FIG. 6B, the electronic device 600c may include a first graphene layer 631 and a second graphene layer 632 spaced apart from each other on the second oxide dielectric material layer 620. The electrodes 651 and 652 may be formed on the first graphene layer 631 and second graphene layer 632.

Referring to FIG. 7A, in an embodiment, an electronic device 700a may be formed as a transistor connected to a data storage DS. The electronic device 700a may include a substrate SUB, a first oxide dielectric material layer 710 on the substrate, a second oxide dielectric material layer 720 in a trench of the first oxide dielectric material layer 710, and a graphene layer 730 on the second oxide dielectric material layer 720 in the trench of the first oxide dielectric material layer 710. The first and second oxide dielectric material layers 710 and 720 respectively may be formed of the same materials as the first and second oxide dielectric material layers 10 and 20 described above with reference to FIGS. 1, 4, and 5. A work function of the graphene layer 730 may vary due to a dipole moment at an interface between the first and second oxide dielectric material layers 710 and 720.

A gate insulating layer 770 may be provided on the first oxide dielectric material layer 710 and the gate insulating layer 770 may extend over the graphene layer 730 and second oxide dielectric material layer 720. A source electrode 751 and a drain electrode 752 are provided on the gate insulating layer 770 and spaced apart from each other. The gate insulating layer 770 may extend between the first oxide dielectric material layer 710 and both the source electrode 751 and the drain electrode 752. The graphene layer 730 may be configured to operate as a gate electrode of the electronic device 770a. Although not illustrated, a conductive material such as a metal or metal alloy may be formed in the trench of the first oxide dielectric material layer 710 and may be surrounded by the graphene layer 730.

The electronic device 700a may further include an insulating layer 785, such as silicon oxide, covering the source electrode 751, gate insulating layer 770, and drain electrode 752. The data storage DS (e.g., capacitor) may be on the insulating layer 785. A contact 775 including an electrically conductive material, such as a metal or metal alloy, may connect the data storage DS to the drain electrode 752.

Referring to FIG. 7B, in an embodiment, an electronic device 700b may differ from the electronic device 700a in FIG. 7A because the gate insulating layer 770, contact 775, source electrode 751, drain electrode 752, and data storage DS may be omitted. Also, the first oxide dielectric material layer 710 may include two trenches spaced apart from each other and each of the trenches may include a graphene interconnect structure like the graphene interconnect structure in FIG. 4. In other words, each of the trenches may include a second oxide dielectric material layer 720 and graphene layer 730 formed therein. As shown in FIG. 7B, the second oxide dielectric material layer 720 may be between the graphene layer 730 and the first oxide dielectric material layer 710.

A conductive layer 790 may electrically connect the graphene interconnect structures to each other by extending over the first oxide dielectric material layer 710 and contacting an upper surface of the graphene layers 730 in the respective graphene interconnect structures. The conductive layer 790 may include a conductive material such as a metal, a metal alloy, or a doped semiconductor.

The electronic device 700b may provide a resistor. Alternatively, in some embodiments, the electronic device 700b may provide a diode structure if the conductive layer 790 includes a first portion and a second portion of opposite conductivity types like the diode structure 680 described in FIG. 6C.

According to an aspect of still another embodiment, a method of manufacturing a graphene interconnect structure may include: preparing the first oxide dielectric material layer 10; forming the second oxide dielectric material layer 20 having a dielectric constant greater than that of the first oxide dielectric material layer 10 by atomic layer deposition (ALD) on a surface of the first oxide dielectric material layer 20; and directly growing the graphene layer 30 by chemical vapor deposition (CVD) on a surface of the second oxide dielectric material layer 20 opposite to the surface on which the first oxide dielectric material layer 10 is located, wherein the second oxide dielectric material layer 20 may include a compound represented by Formula 1:

AₓO_{y} Formula 1

wherein, in Formula 1, A may be at least one selected from Al, Ti, Zr, Hf, Mg, Si, Ge, Y, Lu, La, and Sr, and 0<x≥2, and 0<y≥3.

The first oxide dielectric material layer 10 may be prepared. The first oxide dielectric material layer may include at least one selected from an SiCOH material, porous SiO₂, SiO₂ doped with fluorine, and amorphous boron nitride. The first oxide dielectric material layer 10 may be manufactured by chemical vapor deposition (CVD), high-density plasma CVD (HDPCVD), plasma enhanced CVD (PECVD), pulsed plasma enhanced CVD (pulsed PECVD), spin-on application, or any other suitable method.

For example, when the first oxide dielectric material layer 10 is an SiCOH material, a first precursor (liquid, gas, steam, or vapor) including Si, C, O, and H atoms and an inert carrier such as He or Ar may be provided to a PECVD reactor to mix the precursor with an oxidizing agent of O₂, CO₂, or a combination thereof, thereby preparing the first oxide dielectric material layer 10. In addition to the first precursor, a second precursor (liquid, gas, steam, or vapor) including C, H, optionally O, F, and N atoms may be used. Optionally, a third precursor (liquid, gas, steam, or vapor) including Ge may also be used.

The first precursor may be selected from organic moleculec having a cyclic structure including an SiCOH component such as 1,3,5,7-tetramethylcyclotetrasiloxane (“TMCTS” or “C₄H₁₆O₄Si₄”), octamethylcyclotetrasiloxane (OMCTS), diethoxymethylsilane (DEMS), dimethyldimethoxysilane (DMDMOS), or siloxane. The second precursor may be selected from at least one ring present in a molecule such as cyclopentene oxide (C₅H₈O or CPO) or a hydrocarbon molecule having a branched chain attached to a ring. The third precursor may be formed from a Ge hydride or any other reactant including a Ge source. The PECVD condition may vary depending on the SiCOH material, and for example, a substrate temperature may be in a range of about 300° C. to about 425° C., a high frequency current density may be in a range of about 0.1 W/cm² to about 1.5 W/cm², a flow rate of the first precursor (liquid) may be in a range of about 100 mg/min to about 5,000 mg/min, optionally, a flow rate of the second precursor (liquid) may be in a range of about 50 mg/min to about 10,000 mg/min, optionally, a flow rate of the third precursor (liquid) may be in a range of about 25 mg/min to about 4,000 mg/min, optionally, a flow rate of an inert carrier gas such as He (and/or Ar) may be in a range of about 50 sccm to about 5,000 sccm, a reactor pressure may be in a range of about 1,000 mTorr to about 7,000 mTorr, and a high frequency RF power may be in a range of about 75 W to about 1,000 W. A flow rate of an oxidizing agent added to the PECVD reactor may be in a range of about 10 sccm to about 1,000 sccm. Examples of liquid precursors are described herein, however, a gas precursor such as trimethylsilane may also be used.

The second oxide dielectric material layer 20 having a dielectric constant greater than that of the first oxide dielectric material layer 10 may be formed by atomic layer deposition (ALD) on a surface of the first oxide dielectric material layer 10. A precursor for forming the second oxide dielectric material layer 20 by ALD may include at least one selected from (CH₃)₃Al, TiCl₄, trimethoxy(pentamethylcyclopentadienyl)titanium ((CpMe₅)Ti(OMe)₃), tetrakis(dimethylamino)titanium, Zr[N(CH₃)₂]₄, (dimethylamino)cyclopentadientyl zirconium, ZrCl₄, Hf[N(CH₃)₂]₄, Hf(BH₄)₄, HfCl₄, bis(cyclopentadienyl)magnesium (Mg(Cp)₂), bis(ethylcyclopentadienyl)magnesium (Mg(CpEt)₂), tris(dimethylamino)silane, bis(ethyl-methyl-amino)silane, 1,2-bis(diisopropylamino)disilane, Ge(N, N′—R,R-en)[N(CH₃₎₂]₂ (wherein R is isopropyl or t-butyl), tris(N,N′-diisopropyl-formamidinato)yttrium, {Lu[Cp(Si(CH₃))₂Cl]₂ dimer, tris(isopropyl-cyclopentadienyl)lanthanum (La(iPrCp)₃), strontium bis(isopropylcyclopentadienyl) (Sr(iPrCp)₂), strontium bis(1,2,4-triisopropylcyclopentadienyl) (Sr(1,2,4-iPr₃Cp)₂), strontium bis(tri(isopropyl)cyclopentadienyl (Sr(C₅iPr₃H₂)₂), strontium bis(pentamethylcyclopentadienyl) (Sr(1,2,4-C₅Me₅)₂), strontium bis(n-propyltetramethylcyclopentadienyl) (Sr(nPrMe₄Cp)₂), and strontium bis(tri-tert-butylcyclopentadienyl) (Sr(tBu₃Cp)₂). As a reaction gas, an oxygen-containing precursor such as pure H₂O steam may be used. The atomic layer deposition may be performed by a cycle including: providing a precursor for forming the second oxide dielectric material layer; a first purging for discharging a reaction residue of the precursor for forming the second oxide dielectric material layer; providing an oxygen-containing precursor (e.g., pure H₂O steam); and a second purging for discharging a reaction residue of the the oxygen-containing precursor (e.g., pure H₂O steam). The number of cycling may be determined according to a need for formation of the second oxide dielectric material layer. The atomic layer deposition may be performed at a temperature in a range of about 200° C. to about 900° C.

The second oxide dielectric material layer 20 may include at least one oxide selected from Al₂O₃, TiO₂, ZrO₂, HfO₂, MgO, SiO₂, GeO₂, Y₂O₃, Lu₂O₃, La₂O₃, and SrO.

A thickness of the second oxide dielectric material layer 20 may be in a range of about 0.3 nm to about 5 nm. When a thickness of the second oxide dielectric material layer 20 is within this range, a dipole generated at an interface between the first oxide dielectric material layer 10 and the second oxide dielectric material layer 20 may be effectively transferred to the graphene layer 30 to thereby reduce the specific resistance. Accordingly, RC delay may be limited and/or prevented, and reliability may be secured.

The graphene layer 30 may be directly grown by CVD on a surface of the second oxide dielectric material layer 20 opposite to the surface on which the first oxide dielectric material layer 10 is formed. To allow the graphene layer 30 to directly be grown, a reaction gas may be injected into a reaction chamber. The reaction gas may include a carbon source. The carbon source may include at least one of, for example, a hydrocarbon gas and vapor of liquid precursor including carbon. Here, the hydrocarbon gas may include, for example, methane gas, ethylene gas, acetylene gas, or propylene gas. The liquid precursor including carbon may include, for example, benzene, toluene, xylene, anisol, hexane, octane, isopropyl alcohol, or ethanol. However, these carbon source materials are illustrative only, and various materials, in addition to the carbon source materials, may be used as carbon source materials.

The reaction gas may further include an inert gas and hydrogen gas. The inert gas may include at least one of, for example, argon gas, neon gas, nitrogen gas, helium gas, krypton gas, and xenon gas.

To allow the graphene layer 30 to be directly grown, for example, a mixed gas of a carbon source gas, an inert gas, and a hydrogen gas may be used as a reaction gas. A mixed ratio of the reaction gas injected into the reaction chamber may vary depending on the growing condition of the graphene layer 30.

In the case of directly growing the graphene layer 30 using the PECVD process, power for plasma generation may be applied to the inside of the reaction chamber from a plasma power source. For example, plasma power applied to the growing process of the graphene layer 30 may be 600 W or less, for example, 300 W or less. The plasma power applied to the growing process of the graphene layer 30 may be various types of powers.

Examples of the plasma power may include an RF plasma-generating apparatus or an MW plasma-generating apparatus. The RF plasma-generating apparatus may generate, for example, RF plasma having a frequency in a range of about 3 MHz to about 100 MHz, and the MW plasma-generating apparatus may generate, for example, MW plasma having a frequency in a range of about 0.7 GHz to about 2.5 GHz. However, the frequency ranges are illustrative only, and other frequency ranges may also be used. As a plasma power, a plurality of RF plasma-generating apparatuses or a plurality of MW plasma-generating apparatuses may be used.

When power for plasma generation is applied to the inside of the reaction chamber from the plasma power source, plasma of the reaction gas may be generated inside the reaction chamber. In addition, plasma of the doping gas may be generated inside the reaction chamber.

The CVD may be performed at a temperature in a range of about 250° C. to about 700° C. When the CVD is performed at a temperature lower than 250° C., it may be difficult to decompose the carbon source, and when the CVD is performed at a temperature higher than 700° C., the electronic device may not operate upon application thereof.

A grain size of the graphene layer 30 may be in a range of about 10 nm to about 1 μm.

The graphene layer 30 may be directly grown on the opposite surface of the second oxide dielectric material layer 20 by chemical vapor deposition (CVD). The graphene layer 30 may have a sufficiently low specific resistance to be used as an interconnect structure. In addition, the graphene layer 30 may have excellent processability, as compared with the graphene layer transferred after growth using a catalyst on a separate substrate, and a graphene layer may be effectively realized even in a structure with a narrow line width.

The graphene layer 30 may include 1 to 7 layers.

According to an aspect, the graphene interconnect structure may include: a first oxide dielectric material layer; a second oxide dielectric material layer on a surface of the first oxide dielectric material layer and having a dielectric constant greater than that of the first oxide dielectric material layer; and a graphene layer on a surface of the second oxide dielectric material layer opposite to the surface on which the first oxide dielectric material layer is located. An areal oxygen density of the first oxide dielectric material layer may be different from an areal oxygen density of the second oxide dielectric material layer. Accordingly, a work function of the graphene layer may vary due to a dipole moment generated at an interface between the first oxide dielectric material layer and the second oxide dielectric material layer. As a result, a specific resistance of the graphene interconnect structure may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A graphene interconnect structure comprising:
a first oxide dielectric material layer;
a second oxide dielectric material layer on a surface of the first oxide dielectric material layer, and having a dielectric constant greater than a dielectric constant of the first oxide dielectric material layer; and
a graphene layer on a first surface of the second oxide dielectric material layer opposite to a second surface of the second oxide dielectric material layer, the second surface of the second oxide dielectric material layer being on the first oxide dielectric material layer.

2. The graphene interconnect structure of claim 1, wherein an areal oxygen density of the first oxide dielectric material layer is different from an areal oxygen density of the second oxide dielectric material layer.

3. The graphene interconnect structure of claim 1, wherein a work function of the graphene layer varies due to a dipole moment generated at an interface between the first oxide dielectric material layer and the second oxide dielectric material layer.

4. The graphene interconnect structure of claim 3, wherein a specific resistance of the graphene interconnect structure is reduced by about 1.1 times to about 10 times according to a change in the work function of the graphene layer.

5. The graphene interconnect structure of claim 1, wherein the first oxide dielectric material layer comprises an SiCOH material.

6. The graphene interconnect structure of claim 1, wherein the first oxide dielectric material layer comprises one of tetramethylcyclotetrasiloxane (TOMCATS), octamethylcyclotetrasiloxane (OMCATS), cyclic siloxane 1,1,3,3-tetrahydrido-1,3-disilacyclobutane, 1,1,3,3-tetramethoxy(ethoxy)-1,3 disilacyclobutane, 1,3-dimethyl-1,3-dimethoxy-1,3-disilacyclobutane, 1,3-disilacyclobutane, 1,3-dimethyl-1,3-dihydrido-1,3-disilylcyclobutane, 1,1,3,3-tetramethyl-1,3-disilacyclobutane, 1,1,3,3,5,5-hexamethoxy-1,3,5-trisilane, 1,1,3,3,5,5-hexahydrido-1,3,5-trisilane, 1,1,3,3,5,5-hexamethyl-1,3,5-trisilane, 1,1,1,3,3,3-hexamethoxy(ethoxy)-1,3-disilapropane, 1,1,3,3-tetramethoxy-1-methyl-1,3-disilabutane, 1,1,3,3-tetramethoxy-1,3-disilapropane, 1,1,1,3,3,3-hexahydrido-1,3-disilapropane, 3-(1,1-dimethoxy silaethyl)-1,4,4-trimethoxy-1-methyl-1,4-disilpentane, methoxymethane 2-(dimethoxysilamethyl)-1,1,4-trimethoxy-1,4-disilabutane, methoxymethane 1,1,4-trimethoxy-1,4-disila-2-(trimethoxysilylmethyl) butane, dimethoxymethane, methoxymethane, 1,1,1,5.5.5-hexamethoxy-1,5-disilapentane, 1,1,5,5-tetramethoxy-1,5-disilahexane, 1,1,1,1,4,4,4-hexamethoxy (ethoxy)-1,4-disilylbutane, 1,1,1,4,4,4-hexahydrido-1,4-disilabutane, 1,1,4,4-tetramethoxy(ethoxy)-1,4-dimethyl-1,4-disilabutane, 1,4-bis-trimethoxy(ethoxy)silyl benzene, 1,4-bis-dimethoxymethylsilyl benzene, 1,4-bis-trihydrosilyl benzene, 1,1,1,4,4,4-hexamethoxy (ethoxy)-1,4-disilabut-2-ene, 1,1,1,4,4,4-hexamethoxy(ethoxy)-1,4-disilabut-2-yne, 1,1,3,3-tetramethoxy(ethoxy)-1,3-disilolane, 1,1,3,3-tetramethyl 1,3-disilolane, 1,1,3,3-tetramethoxy(ethoxy)-1,3-disilane, 1,3-dimethoxy(ethoxy)-1,3-dimethyl-1,3-disilane, 1,3-disilane, 1,3-dimethoxy-1,3-disilane, 1,1-dimethoxy (ethoxy)-3.3-dimethyl-1-propyl-3-silabutane, 2-silapropane, or a combination thereof.

7. The graphene interconnect structure of claim 6, wherein the first oxide dielectric material layer further comprises porous SiO₂, SiO₂ doped with fluorine, or amorphous boron nitride.

8. The graphene interconnect structure of claim 1, wherein the second oxide dielectric material layer comprises a compound represented by Formula 1:
AₓO_{y} Formula 1
wherein, in Formula 1,
A is at least one selected from Al, Ti, Zr, Hf, Mg, Si, Ge, Y, Lu, La, and Sr, and 0<x≥2, and 0<y≥3.

9. The graphene interconnect structure of claim 1, wherein the second oxide dielectric material layer comprises at least one of Al₂O₃, TiO₂, ZrO₂, HfO₂, MgO, SiO₂, GeO₂, Y₂O₃, Lu₂O₃, La₂O₃, and SrO.

10. The graphene interconnect structure of claim 1, wherein a thickness of the second oxide dielectric material layer is in a range of about 0.3 nm to about 5 nm.

11. The graphene interconnect structure of claim 1, wherein the graphene layer is directly on the first surface of the second oxide dielectric material layer.

12. The graphene interconnect structure of claim 1, wherein a grain size of the graphene layer is in a range of about 10 nm to about 1 μm.

13. The graphene interconnect structure of claim 1, wherein the graphene layer comprises 1 to 7 layers.

14. An electronic device comprising:
a substrate; and
the graphene interconnect structure of claim 1 on the substrate.

15. A method of manufacturing a graphene interconnect structure, the method comprising:
preparing a first oxide dielectric material layer;
forming a second oxide dielectric material layer by atomic layer deposition (ALD) on a surface of the first oxide dielectric material layer, a dielectric constant of the second oxide dielectric material layer being greater than a dielectric constant of the first oxide dielectric material layer; and
directly growing a graphene layer by chemical vapor deposition (CVD) on a surface of the second oxide dielectric material layer opposite to a surface on which the first oxide dielectric material layer is formed,
wherein the second oxide dielectric material layer comprises a compound represented by Formula 1,
AₓO_{y} Formula 1
wherein, in Formula 1,
A is at least one selected from Al, Ti, Zr, Hf, Mg, Si, Ge, Y, Lu, La, and Sr, and
0<x≥2, and 0<y≥3.

16. The method of claim 15, wherein the first oxide dielectric material layer comprises at least one of an SiCOH material, porous SiO₂, SiO₂ doped with fluorine, and amorphous boron nitride.

17. The method of claim 15, wherein
the forming the second oxide dielectric material layer by ALD uses a precursor, and
the precursor comprises at least one of (CH₃)₃Al, TiCl₄, trimethoxy(pentamethylcyclopentadienyl)titanium ((CpMe₅)Ti(OMe)₃), tetrakis(dimethylamino)titanium, Zr[N(CH₃)₂]₄, (dimethylamino)cyclopentadientyl zirconium, ZrCl₄, Hf[N(CH₃)₂]₄, Hf(BH₄)₄, HfCl₄, bis(cyclopentadienyl)magnesium (Mg(Cp)₂), bis(ethylcyclopentadienyl)magnesium (Mg(CpEt)₂), tris(dimethylamino)silane, bis(ethyl-methyl-amino)silane, 1,2-bis(diisopropylamino)disilane, Ge(N, N′—R,R-en)[N(CH₃₎₂]₂ (wherein R is isopropyl or t-butyl), tris(N,N′-diisopropyl-formamidinato)yttrium, {Lu[Cp(Si(CH₃))₂Cl]₂ dimer, tris(isopropyl-cyclopentadienyl)lanthanum (La(iPrCp)₃), strontium bis(isopropylcyclopentadienyl) (Sr(iPrCp)₂), strontium bis(1,2,4-triisopropylcyclopentadienyl) (Sr(1,2,4-iPr₃Cp)₂), strontium bis(tri(isopropyl)cyclopentadienyl (Sr(C₅iPr₃H₂)₂), strontium bis(pentamethylcyclopentadienyl) (Sr(1,2,4-C₅Me₅)₂), strontium bis(n-propyltetramethylcyclopentadienyl) (Sr(nPrMe₄Cp)₂), and strontium bis(tri-tert-butylcyclopentadienyl) (Sr(tBu₃Cp)₂).

18. The method of claim 15, wherein the second oxide dielectric material layer comprises at least one oxide of Al₂O₃, TiO₂, ZrO₂, HfO₂, MgO, SiO₂, GeO₂, Y₂O₃, Lu₂O₃, La₂O₃, and SrO.

19. The method of claim 15, wherein a thickness of the second oxide dielectric material layer is in a range of about 0.3 nm to about 5 nm.

20. The method of claim 15, wherein in the directly growing the graphene layer, the CVD is performed at a temperature in a range of about 250° C. to about 700° C.

21. The method of claim 15, wherein a grain size of the graphene layer is in a range of about 10 nm to about 1 μm.

22. The method of claim 15, wherein the graphene layer comprises 1 to 7 layers.

23. A graphene interconnect structure comprising:
a first oxide dielectric material layer;
a graphene layer on the first oxide dielectric material layer; and
a second oxide dielectric material layer between the first oxide dielectric material layer and the graphene layer, wherein
the first oxide dielectric material layer and the second oxide dielectric material layer contact each other at an interface and have a structural imbalance at the interface.

24. The graphene interconnect structure of claim 23, wherein
the first oxide dielectric material layer comprises a SiCOH material, and
the second oxide dielectric material layer comprises at least one of Al₂O₃, TiO₂, ZrO₂, HfO₂, MgO, SiO₂, GeO₂, Y₂O₃, Lu₂O₃, La₂O₃, and SrO.

25. The graphene interconnect structure of claim 24, wherein the first oxide dielectric material layer further comprises porous SiO₂, SiO₂ doped with fluorine, or amorphous boron nitride.

26. The graphene interconnect structure of claim 23, wherein
a thickness of the second oxide dielectric material layer is in a range of about 0.3 nm to about 5 nm.

27. The graphene interconnect structure of claim 23, wherein
the graphene layer is directly on a surface of the second oxide dielectric material layer, and
the graphene layer comprises 1 to 7 layers.
